(19) United States
(12) Patent Application Publication
(10) Pub. No.: US 2026/0363111 A1
(43) Pub. Date: Nov. 12, 2026

(54) SEMICONDUCTOR DEVICE

(71) Applicant: Kioxia Corporation, Tokyo (JP)

(72) Inventors: Kana WATANABE, Hiratsuka Kanagawa (JP); Yuta HIBE, Yokohama Kanagawa (JP); Kengo KUMAGAI, Yokohama Kanagawa (JP)

(21) Appl. No.: 19/327,847

(22) Filed: Sep. 12, 2025

(30) Foreign Application Priority Data
Mar. 13, 2025 (JP) 2025-040703

(51) Int. Cl. H10W 70/65; H10W 40/00; H10W 70/685

(52) U.S. Cl. CPC H10W 70/65; H10W 40/00; H10W 70/685

(57) ABSTRACT

A semiconductor device includes a substrate, a temperature sensor, and an electronic component, the temperature sensor and the electronic component being mounted on a first surface of the substrate. The substrate includes a first connecting portion that is on the first surface and connected to the temperature sensor, a second connecting portion that is on the first surface and connected to the electronic component, and a first conductive layer that is spread out in a plane parallel to the first surface. The first conductive layer includes an insulated zone and a first region surrounded by the insulated zone. The first surface includes a second region that is directly above the first region. The first connecting portion is connected to the first conductive layer in the first region. The first connecting portion and the second connecting portion are provided inside the second region of the first surface.

### CROSS-REFERENCE TO RELATED APPLICATION(S)

This application is based upon and claims the benefit of priority from Japanese Patent Application No. 2025-040703, filed Mar. 13, 2025, the entire contents of which are incorporated herein by reference.

### FIELD

Embodiments described herein relate generally to a semiconductor device that includes a substrate.

### BACKGROUND

A semiconductor device that includes a substrate with an electronic component and a temperature sensor mounted thereon is known.

### BRIEF DESCRIPTION OF THE DRAWINGS

FIG. 1 a block diagram illustrating a configuration of a semiconductor device according to a first embodiment.

FIG. 2 is a plan view illustrating a component layout on a substrate according to the first embodiment.

FIG. 3 is a sectional view of a NAND package according to the first embodiment.

FIG. 4 is a bottom view of the NAND package according to the first embodiment.

FIG. 5 is a sectional view of the substrate according to the first embodiment.

FIG. 6 is a perspective view illustrating a positional relationship between a surface layer and an L2 layer of the substrate according to the first embodiment.

FIGS. 7A-7C are plan and sectional views illustrating the surface layer and the L2 layer of the substrate according to the first embodiment.

FIG. 8 is a graph illustrating thermal throttling control according to the first embodiment.

FIGS. 9A-9B are plan and sectional views illustrating a surface layer and an L2 layer in a substrate according to a second embodiment.

FIG. 10 is a bottom view of a NAND package according to the second embodiment.

FIGS. 11A-11B are respectively a plan view illustrating an L2 layer in a substrate and a sectional view illustrating a periphery of a surface layer according to a third embodiment.

FIGS. 12A-12B are respectively a plan view illustrating an L2 layer in a substrate according to a fourth embodiment and a sectional view illustrating a periphery of a surface layer of the substrate according to the fourth embodiment.

### DETAILED DESCRIPTION

Embodiments provide a semiconductor device capable of improving accuracy of temperature measurement of a mounted electronic component.

In general, according to one embodiment, a semiconductor device includes a substrate, a temperature sensor, and a first electronic component that is different from the temperature sensor, the temperature sensor and the first electronic component being mounted on a first surface of the substrate. The substrate includes a plurality of conductive layers that are stacked in a first direction perpendicular to the first surface, a first connecting portion that is provided on the first surface and is connected to the temperature sensor, and a second connecting portion that is provided on the first surface and is connected to the first electronic component. The plurality of conductive layers include a first conductive layer that is spread out in a plane parallel to the first surface. The first conductive layer includes an insulated zone and a first region surrounded by the insulated zone. The first surface includes a second region that is directly above the first region in the first direction. The first connecting portion is connected of the first conductive layer in the first region. The first connecting portion and the second connecting portion are provided inside the second region of the first surface.

Hereinafter, embodiments will be described with reference to the drawings. In the following description, components having substantially the same functions and configurations will be denoted by the same reference signs, and repeated description may be omitted. All description regarding a certain embodiment applies to another embodiment unless explicitly or obviously excluded. In the present specification, “parallel”, “orthogonal” or “same” may also include cases of “substantially parallel”, “substantially orthogonal”, or “substantially same”, respectively. In the present specification, a plurality of members “stacked” may also include the members stacked with deviation in a direction parallel to a stacking surface.

Although specific materials may be illustrated in the present specification, other materials may be employed as long as the effect of the present disclosure is obtained.

### 1. First Embodiment

An example of a semiconductor device according to a first embodiment will be described. Hereinafter, a semiconductor storage device 1 including NAND-type flash memories as nonvolatile memories will be described as an example of the semiconductor device. Examples of such a semiconductor storage device 1 include an SSD (solid state drive). Note that the NAND-type flash memories will be referred to as NAND memories below.

### 1.1 Configuration of Semiconductor Device

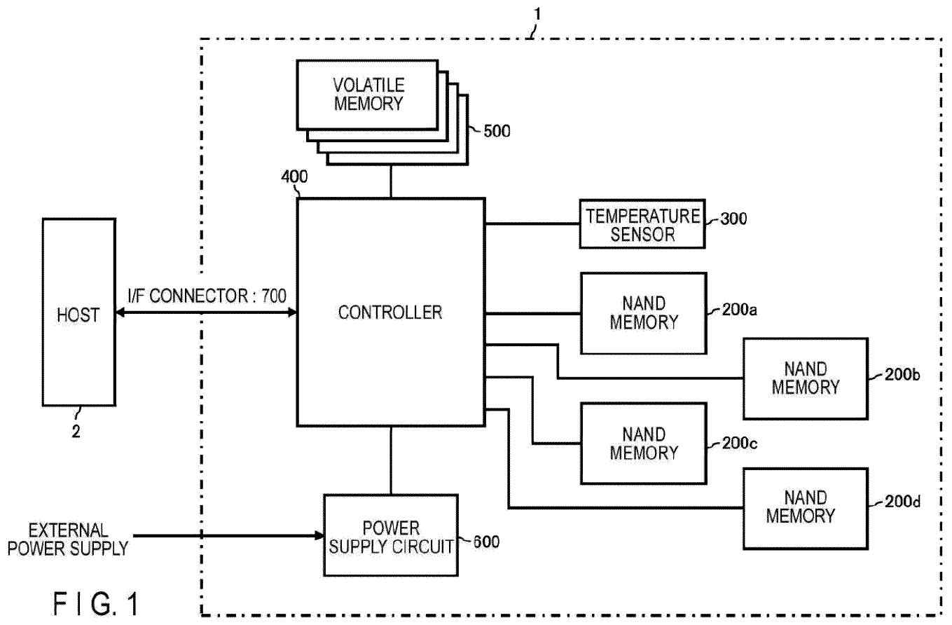

First, a configuration example of the semiconductor storage device 1 will be described with reference to FIG. 1. FIG. 1 is a block diagram illustrating a configuration of the semiconductor storage device 1 according to the first embodiment. As illustrated in FIG. 1, the semiconductor storage device 1 includes NAND memories 200, a temperature sensor 300, a controller 400, DRAMs 500, a power supply circuit 600, and an I/F connector 700. The semiconductor storage device 1 may be configured with a plurality of semiconductor chips. Each component is disposed on a substrate 10, which will be described later.

The NAND memories 200 include memory cell arrays and peripheral circuits and store data in a nonvolatile manner. In the present embodiment, the semiconductor storage device 1 includes four NAND memories 200 (200a to 200d). A structure of the NAND memories 200 will be described later. Note that the number of NAND memories 200 that the semiconductor storage device 1 includes is not limited to four. The number of NAND memories 200 in the semiconductor storage device 1 may be one.

The temperature sensor 300 measures the temperature inside the semiconductor storage device 1 and notifies the controller 400 of the measured temperature. The temperature sensor 300 is, for example, a thermocouple or a thermistor. In the present embodiment, the temperature sensor 300 is used for the purpose of measuring the temperature of the NAND memories 200, among others. In a case where the temperature sensor 300 is a thermocouple, for example, an element inside the temperature sensor 300 is warmed by heat transferred from the NAND memories 200. The temperature sensor 300 measures the thus generated potential difference and converts the potential difference into a temperature.

The controller 400 controls operations of the entire semiconductor storage device 1. The controller 400 is, for example, an SoC (system-on-a-chip). The controller 400 may be configured of a plurality of semiconductor chips. The controller 400 is connected to the NAND memories 200 by a NAND bus (not illustrated) and is connected to a host 2 by the I/F connector 700. The host 2 is, for example, a personal computer or a server. The host 2 and the I/F connector 700 comply with, for example, SATA (Serial ATA (Advanced Technology Attachment)), PCIe™ (PCI Express™ (Peripheral Component Interconnect express)), or NVMe™ (NVM Express™ (Non-Volatile Memory express)).

The controller 400 performs writing of data in the NAND memories 200 and reading of data from the NAND memories 200 in response to requests received from the host 2.

Also, the controller 400 controls operations of the semiconductor storage device 1 on the basis of the measured temperature provided through the notification from the temperature sensor 300. Specifically, the controller 400 performs thermal throttling control on the basis of the measured temperature, for example. The thermal throttling control is a function of lowering performance of components under a specific condition in order to prevent overheating of the components.

For example, there is a concern that stored data may be corrupted under a high-temperature condition and reliability of operations may be degraded in the NAND memories 200. In order to prevent this, the controller 400 activates the thermal throttling control and lowers performance of the semiconductor storage device 1 or the NAND memories 200 in a case where the temperature measured by the temperature sensor 300 exceeds a threshold value. In this manner, a processing load of the NAND memories 200 is lowered, and heat generation is curbed.

Note that the controller 400 preferably performs the thermal throttling control based on the hottest part of the NAND memories 200, in order to ensure their reliability. Also, a detailed operation example of the thermal throttling control will be described later.

The volatile memories 500 are, for example, DRAMs (dynamic random access memories) or SRAMs (static random access memories). The volatile memories 500 temporarily store, for example, firmware, various tables, data written by the host 2, and data read from the NAND memories 200.

Note that the volatile memories 500 may be provided inside the controller 400.

The power supply circuit 600 uses power supplied from an external power supply (the host 2, for example) to apply a voltage to the controller 400, the NAND memories 200, and the like. In a case where the power supply circuit 600 includes a capacitor device, for example, and is not connected to any external power supply, the power supply circuit 600 uses power stored in the capacitor device to apply a voltage to the controller 400, the NAND memories 200, and the like.

### 1.2 Physical Configuration of Semiconductor Storage Device 1

Next, an example of a physical configuration of the semiconductor storage device 1 according to the first embodiment will be described. The semiconductor storage device 1 includes the substrate 10, and the NAND memories 200, the temperature sensor 300, the controller 400, the DRAMs 500, the power supply circuit 600, and the I/F connector 700 are disposed on the substrate 10.

### 1.2.1 Component Layout Configuration

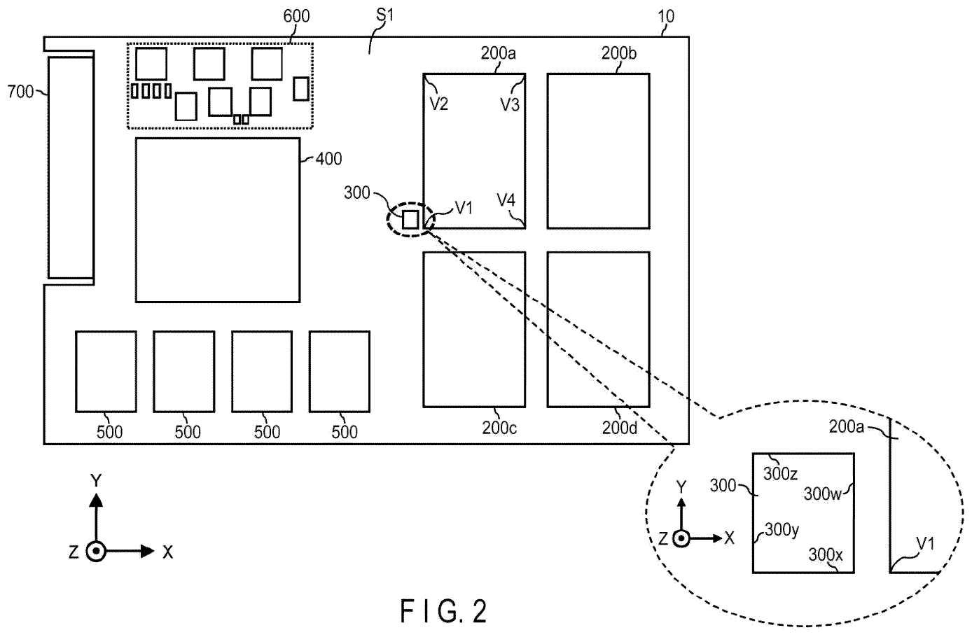

First, a layout of components in the semiconductor storage device 1 will be described with reference to FIG. 2. FIG. 2 illustrates an example of a component layout on the substrate 10 according to the first embodiment. Hereinafter, a surface of the substrate 10 on which the NAND memories 200 and the temperature sensor 300 are mounted will be referred to as a first surface S1.

The substrate 10 is a plate on which various electronic components are disposed and connected. Details of the structure of the substrate 10 will be described later.

As illustrated in FIG. 2, the NAND memories 200, the temperature sensor 300, the controller 400, the DRAMs 500, and the power supply circuit 600 are mounted on the first surface S1 of the substrate 10. Also, the I/F connector 700 is provided on a side surface of the substrate 10.

The NAND memories 200 and the temperature sensor 300 have rectangular shapes, as illustrated in FIG. 2, respectively, in plan view. Hereinafter, the four corners of the NAND memory 200a will be referred to as V1 to V4, respectively, as illustrated in FIG. 2. Specifically, the left lower corner in FIG. 2 will be referred to as V1, and the rest of the corners will be referred to as V2 to V4 in clockwise order. Also, the four edges of the temperature sensor 300 in plan view will be referred to below as 300x, 300y, 300z, and 300w, respectively, as illustrated in FIG. 2. Specifically, the lower edge in FIG. 2 will be referred to as 300x, and the rest of the edges will be referred to as 300y, 300z, and 300w in clockwise order.

Here, an X direction, a Y direction, and a Z direction will be defined. In the drawings referred to below, the X direction and the Y direction are directions that are parallel to the first surface S1 of the substrate 10, the X direction corresponds to a direction that is parallel to the edge 300x of the temperature sensor 300, and the Y direction corresponds to a direction that is parallel to the edge 300y. Moreover, the Z direction is a direction that is perpendicular to the first surface S1 of the substrate 10.

As illustrated in FIG. 2, the temperature sensor 300 is arranged near the NAND memories 200. In particular, the temperature sensor 300 is arranged near V1 of the NAND memory 200a, for example.

In the example illustrated in FIG. 2, the NAND memory 200a is arranged at a position closest to the controller 400 in the XY plane from among the NAND memories 200a to 200d, and the temperature thereof is likely to be raised due to an influence of heat generation of the controller 400. Also, heat is likely to be accumulated at the four corners V1 to V4 of the rectangular shape that each NAND memory 200 has, V1 that is close to the controller 400 in the XY plane, in particular, is also affected by the heat generation of the controller 400, and the temperature thereof is further likely to be raised. Therefore, the temperature sensor 300 can measure the temperature at the point with the highest temperature in the NAND memories 200 by arranging the temperature sensor 300 near the corner V1 of the NAND memory 200a.

### 1.2.2 Structure of NAND Memory 200

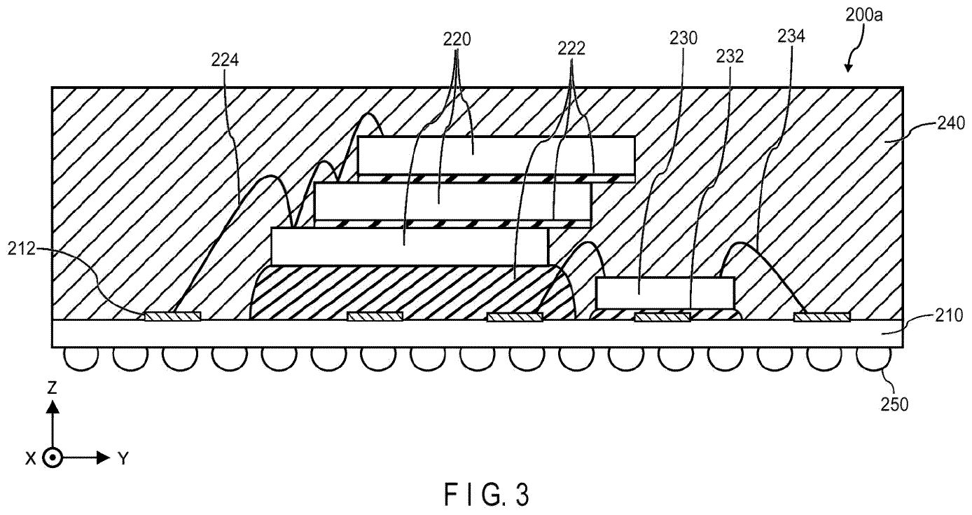

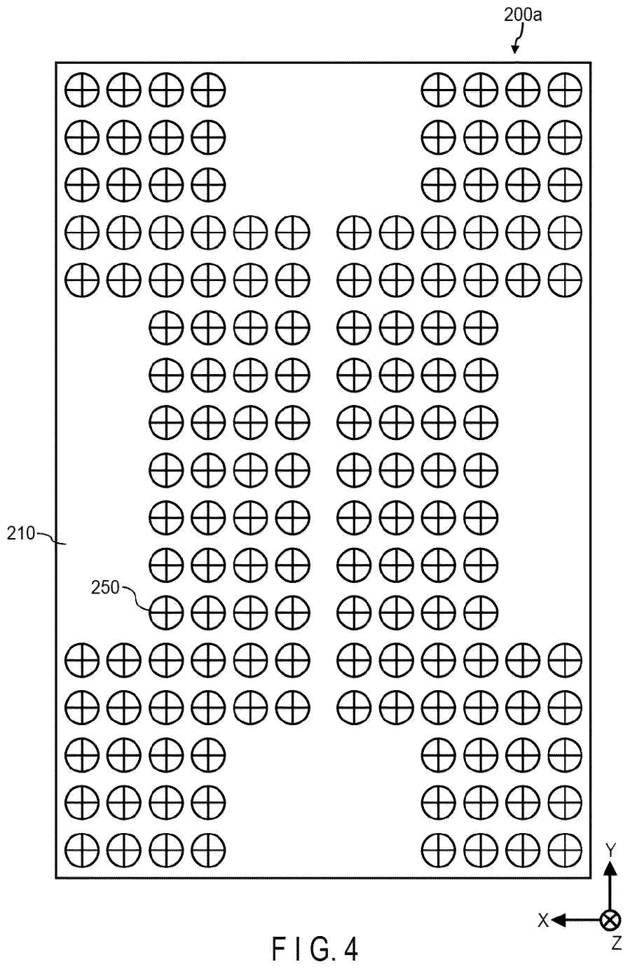

Next, an example of a structure of the NAND memory 200a will be described with reference to FIGS. 3 and 4. Note that the NAND memories 200b to 200d also have structures similar to that of the NAND memory 200a. Hereinafter, the NAND memories 200 (200a to 200d) will also be referred to as NAND packages 200 (200a to 200d).

FIG. 3 is a sectional view of the NAND package 200a according to the first embodiment. As illustrated in FIG. 3, the NAND package 200a includes a package substrate 210, NAND chips 220, adhesives 222, a connection wire 224, a semiconductor chip 230, an adhesive 232, a connection wire 234, a sealing resin 240, and solder balls 250. Also, pads 212 are formed on the package substrate 210.

The package substrate 210 is a plate on which various electronic components are disposed and connected. The pads 212 are formed on the package substrate 210. Note that the package substrate 210 may have a multilayered structure formed by stacking a plurality of layers.

The pads 212 are conductive portions that are provided on a surface of the package substrate 210. The pads 212 are connected to other pads 212 or the solder balls 250 via a wiring provided on the surface of or inside the package substrate 210.

The NAND chips 220 include memory cell arrays and store data in a nonvolatile manner. The NAND chips 220 are mounted on the package substrate 210 via the adhesives 222. Also, the NAND chips 220 are connected to the pads 212 by the connection wires 224. Note that although the three NAND chips 220 are stacked on the package substrate 210 via the adhesives 222 in FIG. 3, the number of NAND chips 220 mounted on the package substrate 210 may be one, two, four or more.

The semiconductor chip 230 includes peripheral circuits to control operations of the NAND chip 220, for example. The peripheral circuits are, for example, a sense amplifier and a row decoder. The semiconductor chip 230 is mounted on the package substrate 210 via the adhesive 232. Also, the NAND chips 220 are connected to the pads 212 via the connection wire 234.

The sealing resin 240 seals the upper surface of the package substrate 210, the NAND chips 220, the adhesives 222, the connection wire 224, the semiconductor chip 230, the adhesive 232, and the connection wire 234. As the sealing resin 240, a thermosetting resin such as an epoxy resin, for example, is used.

The solder balls 250 are connection terminals for electrically connecting the NAND package 200a to the outside. In the present embodiment, the solder balls 250 are connected to pads 110, which will be described later, of the substrate 10. The solder balls 250 are formed of a conductive material such as solder. Note that members that are different from the solder balls 250 may be selected as external connection terminals in accordance with a package form of the NAND package 200a. The package using the solder balls 250 as external connection terminals is referred to as a BGA (ball grid array), in particular.

FIG. 4 is a bottom view of the NAND package 200a according to the first embodiment. FIG. 4 illustrates an example of a layout of the solder balls 250 in the NAND package 200a. As illustrated in FIG. 4, the solder balls 250 are disposed in a grid shape on the lower surface of the package substrate 210. Note that it is not always necessary for all the solder balls 250 to be electrically connected to any of the components or the pads 212 in the NAND package 200a.

### 1.2.3 Structure of Substrate 10

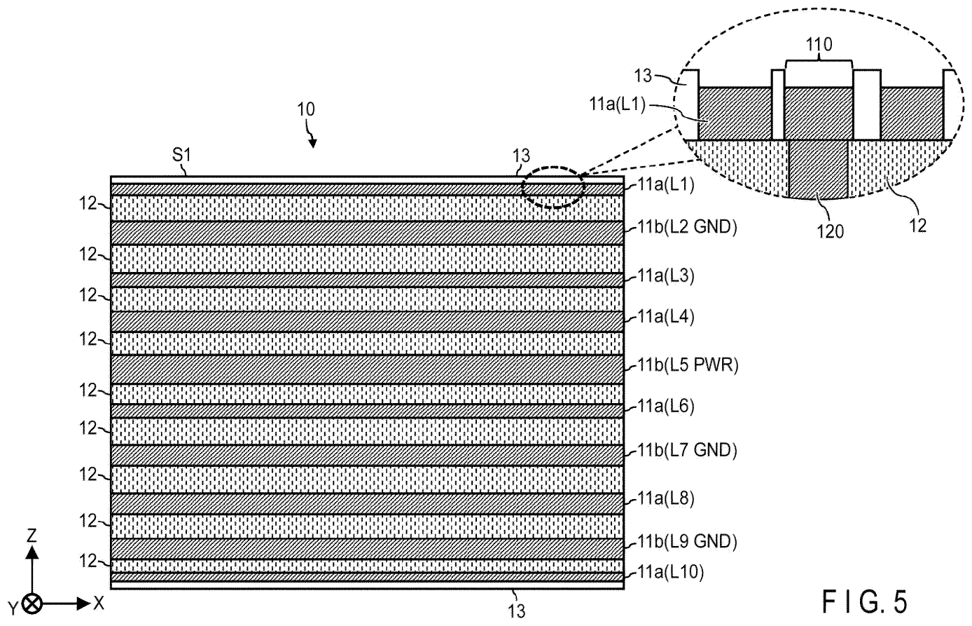

Next, an example of a structure of the substrate 10 will be described with reference to FIGS. 5 to 7.

FIG. 5 is a sectional view of the substrate 10 according to the first embodiment. As illustrated in FIG. 5, the substrate 10 has a multilayered structure formed by stacking a plurality of conductive layers 11 and insulating layers 12 in the Z direction. FIG. 5 illustrates the substrate 10 including ten conductive layers 11 as an example. However, the number of conductive layers 11 that the substrate 10 includes is not limited to ten. Also, the front surface (first surface S1) and the rear surface of the substrate 10 are covered with insulating protective films 13. Note that the plurality of conductive layers 11 are distinguished by assigning the numbers L1 to L10 in order of proximity to the first surface S1 of the substrate 10.

The conductive layers 11 are formed of, for example, copper, nickel, or an alloy thereof. The plurality of conductive layers 11 include signal wiring layers 11a for transmitting and receiving signals, and plane layers 11b serving as ground layers GND and a power supply layer PWR. In FIG. 5, the conductive layers L1, L3, L4, L6, L8, and L10 are the signal wiring layers 11a, and the conductive layers L2, L5, L7, and L9 are the plane layers 11b. In particular, L2, L7, and L9 are the ground layers GND, and L5 is the power supply layer PWR.

Note that the plane layers 11b are plate-shaped conductors spreading along the XY plane. The plane layers 11b may be provided with via holes and insulated zones IZ, which will be described later. The plane layers 11b have a high conductor area density and high heat diffusivity as compared with the signal wiring layers 11a.

The ground layers GND are connected to a ground outside the semiconductor storage device 1 via the I/F connector 700 and supply a reference voltage. Similarly, the power supply layer PWR is connected to an external power supply via the I/F connector 700 and supplies a power voltage.

The insulating layers 12 are formed of, for example, a synthetic resin. Also, the protective films 13 are formed of, for example, a solder resist.

As illustrated in FIG. 5, the pads 110 are provided at places that are not covered with the protective film 13 on the first surface S1 of the substrate 10, such that parts of the conductive layer L1 are exposed from the first surface S1. The pads 110 are connecting portions for electrically connecting the signal wiring layer 11a in the conductive layer L1 of the substrate 10 to the components mounted on the first surface S1 of the substrate 10. The pads 110 are connected to other pads 110 via a wiring formed in the signal wiring layer 11a. Alternatively, the pads 110 are connected to another signal wiring layer 11a other than the conductive layer L1 or a plane layer 11b through a via 120 extending in the Z direction and penetrating through the insulating layers 12. The various components mounted on the first surface S1 of the substrate 10 are electrically connected to each other via the wiring formed in the signal wiring layer 11a and the via 120. Alternatively, the various components mounted on the first surface S1 of the substrate 10 are connected to the ground layers GND and the power supply layer PWR via the wiring formed in the signal wiring layer 11a and the via 120. Note that lands may be provided instead of the pads 110 on the first surface S1.

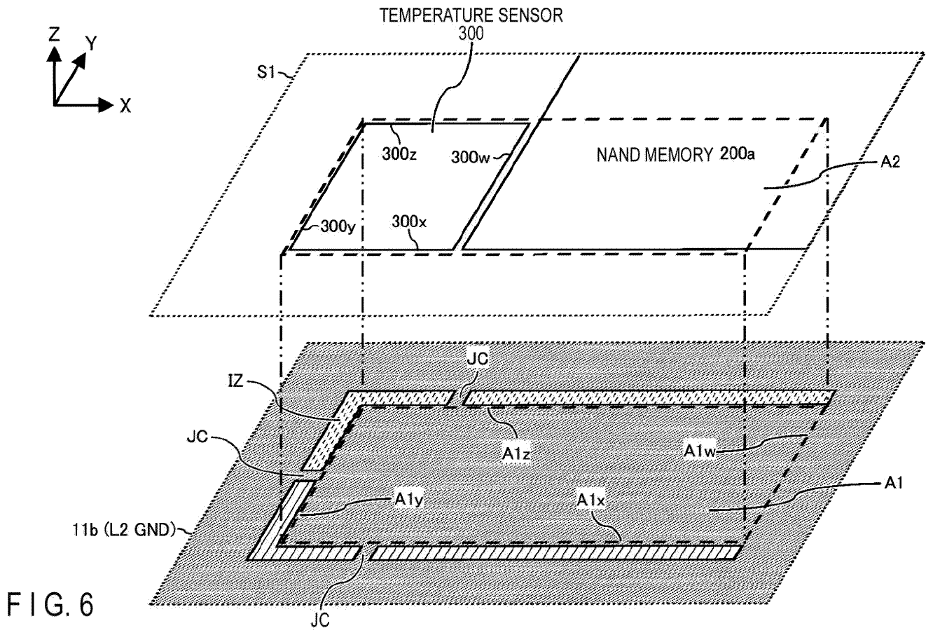

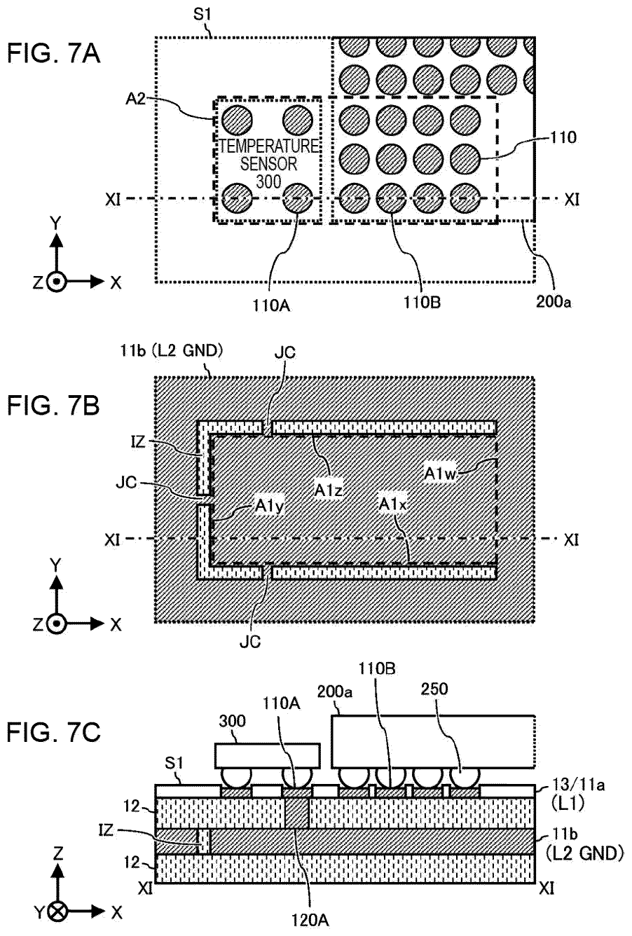

Next, a structure of the conductive layer L2 will be described with reference to FIGS. 6 and 7. The conductive layer L2 is the plane layer 11b that is the closest to the first surface S1 in the Z direction from among the plurality of plane layers 11b stacked in the substrate 10. Also, the conductive layer L2 is the ground layer GND that is the closest to the first surface S1 in the Z direction from among the plurality of ground layers GND stacked in the substrate 10.

FIG. 6 is a perspective view illustrating a positional relationship between the first surface S1 and the conductive layer L2 of the substrate 10 according to the first embodiment. FIG. 7A is a plan view of the first surface S1 of the substrate 10 according to the first embodiment. FIG. 7B is a plan view of the conductive layer L2. FIG. 7C is a sectional view in the vicinity of the first surface S1 of the substrate 10. Note that FIG. 7C is a sectional view along the line segment XI illustrated in FIG. 7A and FIG. 7B. Moreover, FIGS. 6 and 7A-7C illustrate a region in the periphery of the temperature sensor 300 in the substrate 10.

FIGS. 6 and 7A-7C illustrate a first region A1 of the conductive layer L2 and a second region A2 of the first surface S1 by dashed lines, respectively.

The first region A1 of the conductive layer L2 is a region surrounded by the insulated zone IZ provided in the conductive layer L2, as illustrated in FIG. 6 and FIG. 7B. Details of the insulated zone IZ will be described later. In the present embodiment, the first region A1 has a rectangular shape. Hereinafter, four edges of the first region A1 in plan view will be referred to as A1x, A1y, A1z, and A1w, respectively, as illustrated in FIG. 6 and FIG. 7B. Specifically, the lower edge of the first region A1 in FIG. 7B will be referred to as A1x, and the rest of the edges will be referred to as A1y, A1z, and A1w in clockwise order. In the present embodiment, A1x is parallel to the X direction, that is, the edge 300x of the temperature sensor 300, and A1y is parallel to the Y direction, that is, the edge 300y.

The second region A2 of the first surface S1 is a region obtained when the first region A1 of the conductive layer L2 is projected to the first surface S1 in the Z direction, as illustrated in FIG. 6. The second region A2 includes at least a pad 110A connected to the temperature sensor 300 and a pad 110B connected to the NAND memory 200a, as illustrated in FIG. 7A. Note that, as illustrated in FIG. 7C, the pad 110A is connected to the conductive layer L2 through the via 120A. Moreover, the second region A2 includes at least a part of the NAND memory 200 and the temperature sensor 300 in plan view of the substrate 10 as seen in the Z direction.

The insulated zone IZ is a region that is provided in the conductive layer L2 and includes an insulator embedded therein. The insulated zone IZ is formed by forming the conductive layer L2 as a solid metal film, removing a part thereof by etching, and embedding a synthetic resin in the removed area by pressing, for example. The insulated zone IZ has low heat diffusivity (or heat conductivity) as compared with the first region, which is a conductor portion.

Note that the part of the conductive layer L2 formed of the conductor may be referred to below as a conductor portion.

The insulated zone IZ is formed to surround a partial region (first region A1) in the conductive layer L2 in the XY plane. In the present embodiment, the insulated zone IZ surrounds three sides of the first region A1, as illustrated in FIG. 7B. Specifically, the insulated zone IZ surrounds the first region A1 to be in contact with the three edges (A1x, A1y, and A1z) of the first region A1. Note that in the description, the term “surround” is not necessarily limited to completely splitting a certain region apart from the periphery thereof. The insulated zone IZ preferably, but not necessarily, splits apart the conductor portion in the sectional view of the conductive layer L2, as illustrated in FIG. 7C.

Also, the conductive layer L2 is provided with joint conductor areas JC that couple the first region A1 and the external conductor portion with the insulated zone IZ interposed therebetween. The joint conductor areas JC are formed by performing etching with a part of a target region protected by a resist at the time of etching for forming the insulated zone IZ, for example. As illustrated in FIG. 7B, one joint conductor area JC is provided at each of the parts in contact with the three edges (A1x, A1y, and A1z) of the first region A1, for example. Note that the number of joint conductor areas JC may be not more than two or not less than four.

### 1.3 Operations of Controller 400

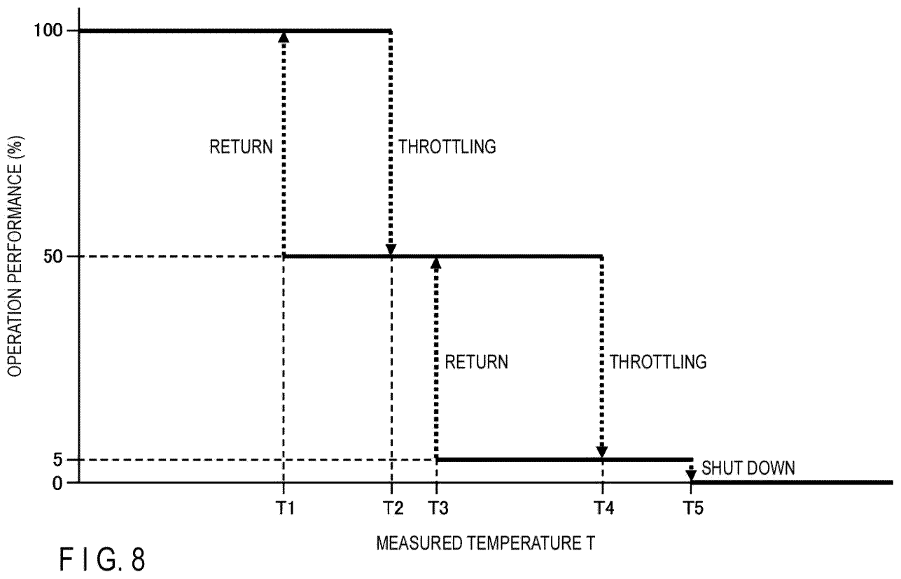

Next, an example of control that is performed by the controller 400 on the basis of the temperature measured by the temperature sensor 300 will be described with reference to FIG. 8. In the present embodiment, the controller 400 performs thermal throttling control on the basis of the temperature measured by the temperature sensor.

FIG. 8 is a graph illustrating an overview of the thermal throttling control performed by the controller 400 according to the first embodiment. The horizontal axis represents a temperature T measured by the temperature sensor 300, and the vertical axis represents operation performance [%] of the semiconductor storage device 1. The operation performance of the semiconductor storage device 1 is, for example, writing performance or reading performance of the semiconductor storage device 1. Note that FIG. 8 defines, as 100%, the operation performance of the semiconductor storage device 1 in a state where the thermal throttling control is not executed.

The controller 400 activates the thermal throttling control once the temperature measured by the temperature sensor 300 reaches T2 in a state where the thermal throttling control is not executed, and lowers the operation performance of the semiconductor storage device 1. In FIG. 8, the controller 400 lowers the operation performance of the semiconductor storage device 1 to 50%. The controller 400 lowers the operation performance of the semiconductor storage device 1 by limiting the number of requests received from the host 2, limiting the clock frequency, or lowering a data transfer rate inside the semiconductor storage device 1, for example. In this manner, a processing load on the controller 400 and the NAND memories 200 inside the semiconductor storage device 1 is reduced, and it is possible to curb a temperature rise.

If the temperature measured by the temperature sensor 300 reaches T4 (T4>T2, for example) after the thermal throttling control is activated, the controller 400 further lowers the operation performance of the semiconductor storage device 1. In FIG. 8, the controller 400 lowers the operation performance of the semiconductor storage device 1 to 5%. In this manner, the processing load is further reduced, and it is possible to curb a temperature rise.

If the temperature measured by the temperature sensor 300 reaches T5 (T5>T4, for example) after the controller 400 limits the operation performance of the semiconductor storage device 1 to 5%, then the controller 400 shuts down the semiconductor storage device 1. In this manner, heat generation due to the processing load is eliminated, and it is possible to prevent the data stored in the NAND memories 200 from being corrupted, for example.

On the other hand, if the temperature measured by the temperature sensor 300 reaches T1 (T1<T2, for example) while the thermal throttling control is active, the controller 400 deactivates the thermal throttling control and returns the operation performance of the semiconductor storage device 1 to 100%.

Similarly, if the temperature measured by the temperature sensor 300 reaches T3 (T3<T4, for example) while the operation performance of the semiconductor storage device 1 is limited to 5%, the controller 400 returns the operation performance of the semiconductor storage device 1 to 50%.

Note that the conditions (T1 to T5) for activating the thermal throttling control, the operation performance (%) after the activation, and the number of stages for limitation can be arbitrarily designed. Also, the thermal throttling control may be activated by a combination of the measured temperature conditions and other conditions. Moreover, the controller 400 may determine activation conditions using a value obtained by compensating for the temperature measured by the temperature sensor 300 or the like.

### 1.4 Effect

The semiconductor storage device 1 according to the present embodiment can improve the accuracy of temperature measurement of the electronic component performed by the temperature sensor 300. Hereinafter, details of this effect will be described using the example provided for the present embodiment.

In general, the plane layers 11b have a high conductor area density and high heat diffusivity as compared with the signal wiring layers 11a in the substrate 10 in which the plurality of conductive layers 11 are stacked, and thus serve as the main heat diffusing routes in the substrate. For example, heat generated by the NAND memories 200 implemented on the substrate 10 and transferred to the substrate 10 is delivered to the plane layers 11b in the substrate 10 and is finally diffused to the entire plane layers 11b. Note that the heat diffusing routes from the substrate surface (first surface S1) to the inside of the substrate include a heat diffusing route via the via 120 (conductor) in addition to the heat diffusion via the insulating layers 12.

Here, a part of the heat generated by the NAND memories 200 and diffused inside the substrate 10 (particularly, in the plane layers 11b) is also transferred to the temperature sensor 300. In order to accurately measure the temperature, it is important for the heat generated by the NAND memories 200 to be sufficiently transferred to the temperature sensor 300.

In a substrate in the related art, heat generated by NAND memories and transferred to plane layers is diffused in any directions along the plane layers, and the heat from the NAND memories is diffused before being sufficiently transferred to a temperature sensor, which is one of the factors of causing a difference between the temperature of the NAND memories and the temperature measured by the temperature sensor.

Thus, in the substrate 10 according to the present embodiment, the insulated zone IZ is provided in the conductive layer L2 of the substrate 10, to surround the first region A1 corresponding to a part that is immediately below, in the Z direction, the second region A2 including the pads 110A and 110B that are portions connected to the NAND memory 200a in the first surface S1, as illustrated in FIGS. 6 and 7.

The insulated zone IZ has low heat diffusivity as compared with the conductor portion of the conductive layer L2. Therefore, diffusion of heat from the first region A1 is curbed. Specifically, the insulated zone IZ limits diffusion of heat passing through the edges A1x, A1y, and A1z of the first region A1. In this manner, heat generated by the NAND memory 200a and transferred to the conductive layer L2 remains in the first region A1, and the amount of heat transferred to the temperature sensor 300 increases. In this manner, the semiconductor storage device 1 can reduce the difference between the temperature of the NAND memory 200a and the temperature measured by the temperature sensor 300 and improve the accuracy of the temperature measurement.

Also, the conductive layer L2 is the plane layer 11b that is the closest to the first surface S1 and is a layer to which the heat from the NAND memories 200 is most likely to be transferred from among the plurality of plane layers 11b provided in the substrate 10. Therefore, it is possible to more efficiently limit diffusion of the heat transferred from the NAND memories 200 to the substrate 10 by providing the insulated zone IZ in the conductive layer L2.

Also, the pad 110A included in the second region A2 is connected to the first region of the conductive layer L2 through the via 120A, as illustrated in FIGS. 7A and 7C in the substrate 10 according to the present embodiment. The via 120A is a conductor and has higher heat conductivity than the insulating layers 12. Therefore, heat remaining in the first region A1 is more efficiently transferred to the temperature sensor 300 via the pad 110A and the via 120A, and it is thus possible to increase the amount of heat transferred to the temperature sensor 300.

Also, the second region A2 includes the temperature sensor 300 in plan view of the substrate 10 as seen in the Z direction in the present embodiment. In this manner, heat transferred from the first region A1 of the conductive layer L2 to the first surface S1 of the substrate 10 becomes likely to be transferred to the temperature sensor 300 via air between the substrate 10 and the temperature sensor 300 as well, for example, and it is thus possible to increase the amount of heat transferred to the temperature sensor 300.

Also, the second region A2 includes a part of the NAND memory 200a in plan view of the substrate 10 as seen in the Z direction in the present embodiment. In particular, the second region A2 includes the corner V1 of the NAND memory 200a, which is the closest to the controller 400 in plan view from among the four corners. In this manner, heat transferred from the NAND memory 200a to the substrate 10 via the air therebetween, for example, becomes likely to be transferred to the first region A1, and it is thus possible to increase the amount of heat transferred to the temperature sensor 300.

In the present embodiment, the insulated zone IZ of the conductive layer L2 is provided with the joint conductor areas JC. In a semiconductor device, a high communication speed may be required for communication between components via a substrate. Here, if the insulated zone IZ is provided in the conductive layer L2, it becomes necessary for a current having flowed from the temperature sensor 300 and the NAND memory 200a, for example, to bypass the insulated zone IZ and to flow to the outside of the first region A1. There is a concern that such bypassing of the current may lead to a decrease in communication speed. On the other hand, the substrate 10 according to the present embodiment can curb a decrease in communication speed as described above by the joint conductor areas JC provided in the conductive layer L2 serving as escaping routes for the current.

### 2. Second Embodiment

Next, a second embodiment will be described. In a semiconductor storage device 1 according to the second embodiment, a pad 110B that is included in a second region A2 and is connected to a NAND memory 200a is connected to a first region A1 of a conductive layer L2 through a via. Hereinafter, differences from the first embodiment will be described.

### 2.1 Structure of Substrate 10

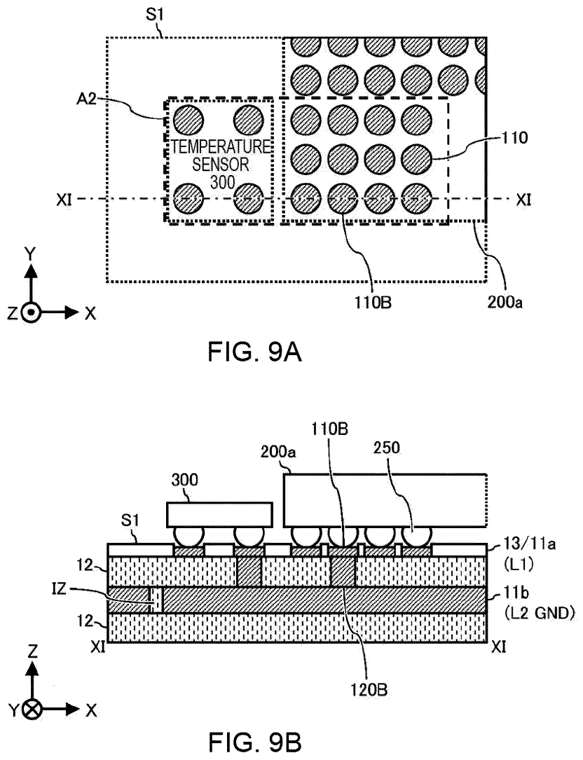

An example of a structure of a substrate 10 according to the second embodiment will be described with reference to FIGS. 9A-9B. FIG. 9A is a plan view of a first surface S1 of the substrate 10 according to the second embodiment, and FIG. 9B is a sectional view in the vicinity of the first surface S1 of the substrate 10. Note that FIG. 9B is a sectional view along the line segment XI illustrated in FIG. 9A. Also, FIGS. 9A-9B illustrate a region in the periphery of a temperature sensor 300 in the substrate 10. As illustrated in FIG. 9B, the pad 110B connected to the NAND memory 200a is connected to the conductive layer L2 through a via 120B.

### 2.2 Structure of NAND Memory 200

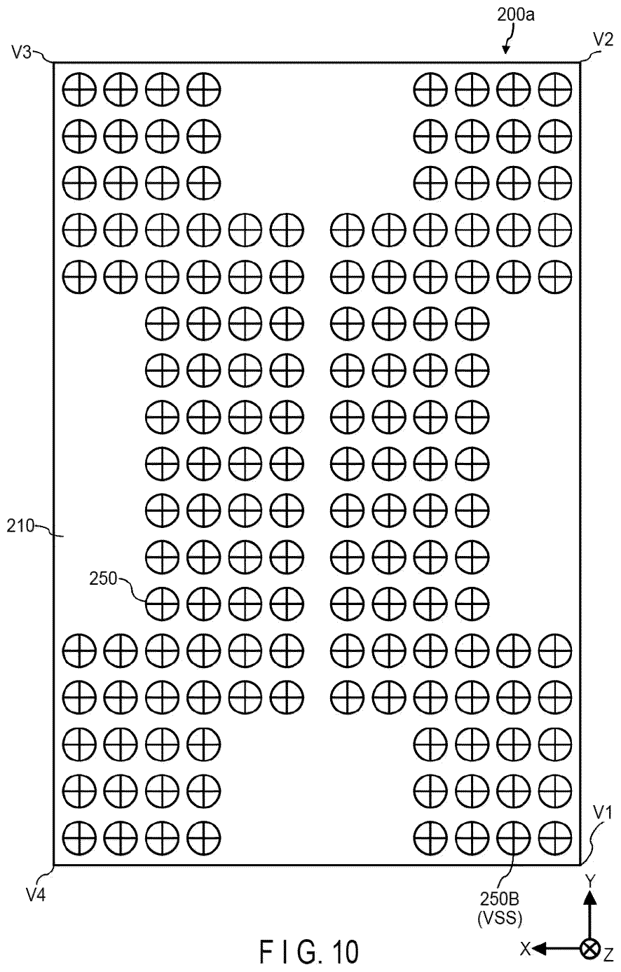

Next, an example of a structure of the NAND memory 200a (NAND package 200a) will be described with reference to FIG. 10.

FIG. 10 is a bottom view of the NAND package 200a according to the second embodiment. FIG. 10 illustrates an example of a layout of solder balls 250 in the NAND package 200a. As illustrated in FIG. 10, a solder ball 250B serving as a ground terminal VSS is provided at a position close to a corner of the lower surface of a substrate 210 in the present embodiment. In particular, the solder ball 250B is provided at a position close to a corner V1. The ground terminal VSS is a terminal that supplies a reference voltage to the NAND package 200a and is electrically connected to a ground layer GND in the substrate 10.

Note that the solder ball 250B serving as the ground terminal VSS may be provided at a position close to at least any of the other corners V2, V3, and V4 in addition to the corner V1 in the NAND package 200a. Also, similar configurations may be used for the NAND packages 200b, 200c, and 200d.

### 2.3 Effect

The semiconductor storage device 1 according to the present embodiment has an effect similar to that of the semiconductor storage device 1 according to the first embodiment.

Also, the pad 110B included in the second region A2 is connected to the first region of the conductive layer L2 through the via 120B, as illustrated in FIGS. 9A-9B in the semiconductor storage device 1 according to the present embodiment. Therefore, heat generated by the NAND memory 200a is more efficiently transferred to the first region via the pad 110B and the via 120B. It is thus possible to increase the amount of heat transferred from the NAND memory 200a to the temperature sensor 300 via the first region.

### 3. Third Embodiment

Next, a third embodiment will be described. In a semiconductor storage device 1 according to the third embodiment, an insulated zone IZ provided in a conductive layer L2 is formed to surround four sides of a partial region (first region A1) in the conductive layer L2. Hereinafter, differences from the first embodiment will be described on the basis of the first embodiment.

### 3.1 Structure of Substrate 10

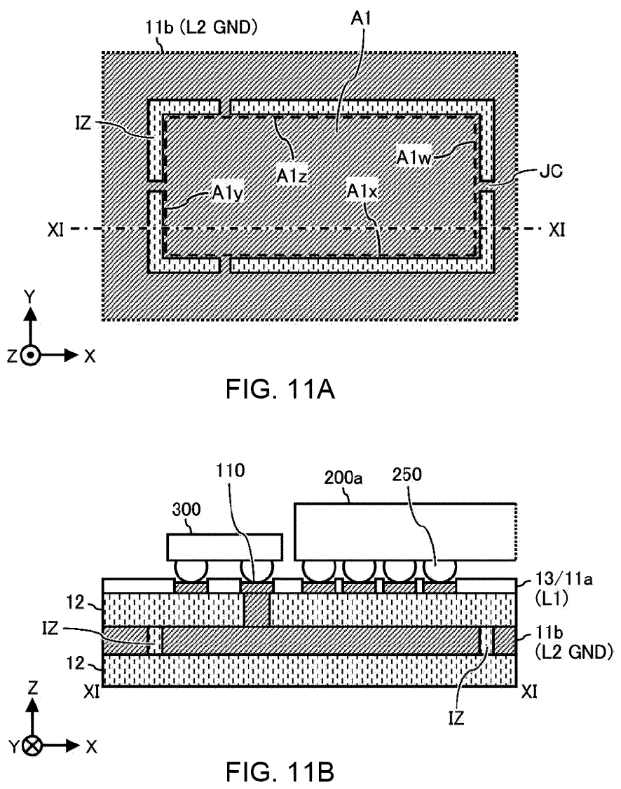

An example of a structure of a substrate 10 according to the third embodiment will be described with reference to FIGS. 11A-11B. FIG. 11A is a plan view of the conductive layer L2 in the substrate 10 according to the third embodiment, and FIG. 11B is a sectional view in the vicinity of a first surface S1 of the substrate 10. Note that FIG. 11B is a sectional view along the line segment XI illustrated in FIG. 11A. Also, FIGS. 11A-11B illustrate a region in the periphery of a temperature sensor 300 in the substrate 10.

In the present embodiment, the insulated zone IZ surrounds the four sides of the first region A1, as illustrated in FIG. 11A. Specifically, the insulated zone IZ surrounds the first region A1 to be in contact with four edges (A1x, A1y, A1z, and A1w) of the first region A1.

Moreover, one joint conductor area JC is provided at each of parts in contact with the four edges (A1x, A1y, A1z, and A1w) of the first region A1, as illustrated in FIG. 11A.

### 3.2 Effect

The semiconductor storage device 1 according to the present embodiment has an effect similar to that of the semiconductor storage device 1 according to the first embodiment.

In addition, the insulated zone IZ surrounds the four sides of the first region A1, as illustrated in FIG. 11A in the semiconductor storage device 1 according to the present embodiment. In this manner, heat diffusion from the first region A1 is further curbed. Specifically, the insulated zone IZ limits heat diffusion passing through the edges A1x, A1y, A1z, and A1w of the first region A1. In this manner, heat generated by the NAND memory 200a and transferred to the conductive layer L2 further remains in the first region A1, and it is possible to further increase the amount of heat transferred to the temperature sensor 300.

### 4. Fourth Embodiment

Next, a fourth embodiment will be described. In a semiconductor storage device 1 according to the fourth embodiment, the thickness of each joint conductor area JC formed in a conductive layer L2 is thinner than the thickness of the conductive layer L2. Hereinafter, differences from the first embodiment will be described on the basis of the first embodiment.

### 4.1 Structure of Substrate 10

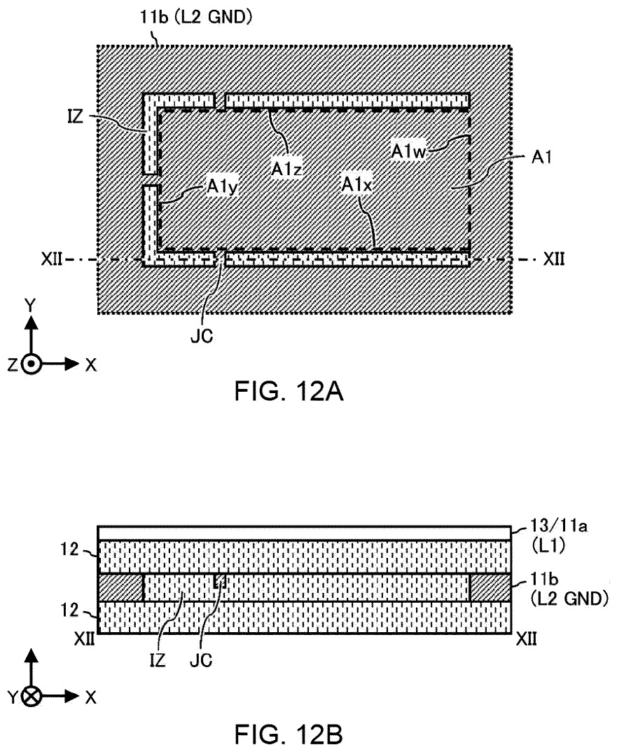

An example of a structure of a substrate 10 according to the fourth embodiment will be described with reference to FIGS. 12A-12B. FIG. 12A is a plan view of a first surface S1 of the substrate 10 according to the fourth embodiment, and FIG. 12B is a sectional view in the vicinity of the first surface S1 of the substrate 10. Note that FIG. 12B is a sectional view along the line segment XII illustrated in FIG. 12A. Also, FIGS. 12A-12B illustrate a region in the periphery of a temperature sensor 300 in the substrate 10.

As illustrated in FIG. 12B, the thickness of each joint conductor area JC formed in the conductive layer L2 in the Z direction is thinner than the thickness of the conductive layer L2 or an insulated zone IZ in the Z direction. For example, the thickness of the joint conductor area JC is half the thickness of the conductive layer L2.

Note that all the joint conductor areas JC provided in the conductive layer L2 may have a thickness that is thinner than the thickness of the conductive layer L2, or some of the joint conductor areas JC may have a thickness that is thinner than the thickness of the conductive layer L2. Also, the thickness may not be uniform in each joint conductor area JC.

### 4.2 Effect

The semiconductor storage device 1 according to the present embodiment has an effect similar to that of the semiconductor storage device 1 according to the first embodiment.

Also, the thickness of the joint conductor areas JC is thinner than the thickness of the conductive layer L2, as illustrated in FIG. 12B in the semiconductor storage device 1 according to the present embodiment. Although the joint conductor areas JC may serve as heat diffusion routes from the first region A1, heat diffusion passing through the joint conductor areas JC is curbed by reducing the thickness of the joint conductor areas JC in the present embodiment. In this manner, it is possible to further curb heat diffusion from the first region A1 while leaving escaping routes for a current from the first region A1.

Note that the configurations according to the first to fourth embodiments can be arbitrarily combined.

Note that although the semiconductor storage device as a semiconductor device and the NAND package as an electronic component are taken as an example in the above embodiments, semiconductor devices are not limited thereto as long as they perform control based on a temperature. Also, in a case where a temperature sensor is mounted inside a sealed package form such as a NAND package, for example, it is possible to obtain an effect similar to those of the embodiments by applying the above configurations to components (for example, NAND chips) and the temperature sensor inside the package and a package substrate within the package.

Also, information regarding the measured temperature that is provided through a notification from the temperature sensor 300 to the controller 400 is not limited to a value indicating a measured temperature in Celsius and may be a level indicating a temperature zone of the measured temperature or a measured potential difference, for example, in the embodiments.

Also, the substrate included in the semiconductor device may have a double-sided structure, with components mounted on both surfaces of the substrate. In a case where the substrate 10 of the semiconductor storage device 1 has a double-sided structure, for example, the configurations of the embodiments may be applied to both surfaces of the substrate 10 by assuming both surfaces as first surfaces S1.

Also, the insulated zone IZ may be provided in the plurality of plane layers 11b in the substrate 10. The joint conductor areas JC may also be provided in the plurality of plane layers 11b in the substrate 10.

Also, the insulated zone IZ is not limited to the region with an insulator embedded therein, and the region may be, for example, a hollow. Since heat diffusivity (or heat conductivity) of the region is smaller than that of the conductor portion of the conductive layer L2 in this case as well, it is possible to obtain the effect of the embodiments.

Moreover, the shapes of the first region A1 and the second region A2 are not limited to the rectangular shapes. In other words, the insulated zone IZ may be formed to surround a circular region, a triangular region, or an oval region, for example. It is possible to obtain an effect similar to that of the embodiments by configuring the pads connected to the temperature sensor and the electronic component so as to be included in the second region A2 in this case as well.

In addition, although the controller 400 included in the semiconductor storage device 1 performs control based on the temperature measured by the temperature sensor 300 in the embodiments, the present invention is not limited thereto. In other words, the host 2 may be notified of the temperature measured by the temperature sensor 300, and the host 2 may perform control based on the measured temperature, for example. In this case, the control performed by the host 2 may not be targeted at the semiconductor device or the components inside the semiconductor device and may be, for example, activation of a cooling fan or control to lower a room temperature in a server room where the semiconductor storage device 1 is installed.

While certain embodiments have been described, these embodiments have been presented by way of example only, and are not intended to limit the scope of the inventions. Indeed, the novel devices and methods described herein may be embodied in a variety of other forms; furthermore, various omissions, substitutions, and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a substrate; and
a temperature sensor and a first electronic component that is different from the temperature sensor, the temperature sensor and the first electronic component being mounted on a first surface of the substrate, wherein
the substrate includes
a plurality of conductive layers that are stacked in a first direction perpendicular to the first surface,
a first connecting portion that is provided on the first surface and is connected to the temperature sensor, and
a second connecting portion that is provided on the first surface and is connected to the first electronic component,
the plurality of conductive layers include a first conductive layer that is spread out in a plane parallel to the first surface,
the first conductive layer includes an insulated zone and a first region surrounded by the insulated zone,
the first surface includes a second region that is directly above the first region in the first direction,
the first connecting portion is connected the first conductive layer in the first region, and
the first connecting portion and the second connecting portion are provided inside the second region of the first surface.

2. The semiconductor device of claim 1, wherein the first conductive layer includes a joint conductor area that couples the first region and an outer region of the first conductive layer that is outside the first region with the insulated zone interposed therebetween.

3. The semiconductor device of claim 2, wherein the insulated zone surrounds three sides of the first region.

4. The semiconductor device of claim 3, wherein
the first region and the second region have rectangular shapes, and
the insulated zone extends along at least three edges of the first region.

5. The semiconductor device of claim 2, wherein the insulated zone surrounds four sides of the first region.

6. The semiconductor device of claim 5, wherein
the first region and the second region have rectangular shapes, and
the insulated zone extends along four edges of the first region.

7. The semiconductor device of claim 1, wherein
the temperature sensor has a rectangular shape when viewed in the first direction, and
the insulated zone includes a part that extends in a second direction that is parallel to one edge of the temperature sensor and is parallel to the first surface.

8. The semiconductor device of claim 1, wherein an operation of the first electronic component is controlled on the basis of a measured temperature measured by the temperature sensor.

9. The semiconductor device of claim 8, wherein the first electronic component is a nonvolatile memory.

10. The semiconductor device of claim 9, wherein the first electronic component is a NAND-type flash memory.

11. The semiconductor device of claim 8, further comprising:
a controller,
wherein the controller controls an operation of the first electronic component on the basis of the measured temperature.

12. The semiconductor device of claim 1, wherein the first conductive layer is a planar conductive layer.

13. The semiconductor device of claim 1, wherein
the plurality of conductive layers include at least one planar conductive layer including the first conductive layer, and
the first conductive layer is closest to the first surface in the first direction from among the at least one planar conductive layer.

14. The semiconductor device of claim 13, wherein the first conductive layer is a ground layer.

15. The semiconductor device of claim 1, wherein the first connecting portion is connected to the first conductive layer through a via extending in the first direction.

16. The semiconductor device of claim 15, wherein the second connecting portion is connected to the first conductive layer through a via extending in the first direction.

17. The semiconductor device of claim 1, wherein
the first electronic component has a rectangular shape when viewed in the first direction, and
a first projection point obtained by projecting a first vertex from among four vertices of the first electronic component to the first conductive layer in the first direction is included in the first region.

18. The semiconductor device of claim 17, further comprising:
a controller that is mounted on the first surface of the substrate,
wherein the first vertex is closest to the controller from among the four vertices.

19. The semiconductor device of claim 1, wherein
the first conductive layer further includes a joint conductor area extending through the insulated zone in a second direction parallel to the first surface, and electrically coupling the first region and an outer region of the first conductive layer that is outside the first region with the insulated zone interposed therebetween, and
a thickness of the joint conductor area in the first direction is less than a thickness of the first conductive layer in the first region and the outer region in the first direction.

20. The semiconductor device of claim 1, wherein the insulated zone is not a via.
